(19) United States
(12) Patent Application Publication
(10) Pub. No.: US 2024/0234190 A9
(43) Pub. Date: Jul. 11, 2024

(54) TRANSFER OF MICRO DEVICES

(71) Applicant: VueReal Inc., Waterloo (CA)

(72) Inventors: Gholamreza CHAJI, Waterloo (CA); Ehsanollah FATHI, Waterloo (CA); Hossein Zamani SIBONI, Waterloo (CA); Dana Saud Yousef AYYASH, Waterloo (CA)

(73) Assignee: VueReal Inc., Waterloo, ON (CA)

(21) Appl. No.: 18/546,715

(22) PCT Filed: Feb. 22, 2022
(86) PCT No.: PCT/CA2022/050250

§ 371 Date: Aug. 16, 2023

Related U.S. Application Data
(60) Provisional application No. 63/152,026, filed on Feb. 22, 2021.

(51) Int. Cl. H01L 21/683; H01L 21/67; H01L 25/00; H01L 27/144

(52) U.S. Cl. CPC H01L 21/6835; H01L 21/67144; H01L 25/50; H01L 27/1443; H01L 2221/68322; H01L 2221/68354; H01L 2221/68363

(57) ABSTRACT

The present disclosure relates to transfer of a selected set of microdevices from a donor substrate to a receiver/system substrate while there can be already microdevices transferred in the system substrate. In particular the invention deals with pads with a hard base and soft shell. In addition, use of a stage to facilitate the microdevice transfer is detailed.

### FIELD OF THE INVENTION

The present disclosure relates to transfer of a selected set of microdevices from a donor substrate to a receiver/system substrate while there can be already microdevices transferred in the system substrate.

### BRIEF SUMMARY

According to one of the embodiments, there is a method to transfer microdevices the method comprising, forming a buffer layer on a donor substrate, having microdevices located on a top of the buffer layer, having a system substrate with transferred microdevices on pads made of a soft material; having other pads made of the soft material on the system substrate without microdevices, and bringing the donor and system substrate closer such that selected microdevices to be transferred are close to associated pads on the system substrate.

According to another embodiment, there is a method to transfer microdevices the method comprising, forming a buffer layer on a donor substrate, having microdevices located on a top of the buffer layer, having a system substrate with transferred microdevices on pads, with the pads having a hard material base and a soft shell, having other pads having a hard material base and a soft shell on the system substrate without microdevices, and bringing the donor and system substrate closer such that selected microdevices to be transferred are close to associated pads on the system substrate.

### BRIEF DESCRIPTION OF THE DRAWINGS

The foregoing and other advantages of the disclosure will become apparent upon reading the following detailed description and upon reference to the drawings.

FIG. 1A shows non-flatness of donor/cartridge substrate or system substrate.

FIG. 1B shows selected microdevices are touching or getting close to the selected pads.

FIG. 2A shows the donor substrate has a buffer layer.

FIG. 2B shows a pad structure with hard core 152-a and soft shell.

FIG. 2C shows a post on the backplane to further prevent the nonuniform pressure.

FIG. 2D shows posts can be also formed on the donor substrate

FIGS. 3A and 3B show the pads on the system substrate are formed on a stage.

While the present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of an invention as defined by the appended claims.

### DETAILED DESCRIPTION

The invention relates to transfer of a selected set of microdevices from a donor substrate to a receiver/system substrate while there can already be microdevices transferred in the system substrate. Or in another case, other structures exist in the receiver substrate that can interfere with the transfer. In this invention, we use the previously transferred microdevice to explain the invention, however similar topics can be applied to the other structures.

Microdevices can be microLED, OLED, microsensors, MEMs, and any other type of devices.

In one case, the microdevice has a functional body and contacts. The contacts can be electrical, optical, or mechanical contacts.

In the case of an optoelectronic microdevices, the microdevice can have functional layers and charge carrying layers. Where charge carrying layers (doped layers, ohmics and contacts) transfer the charges (electron of hole) between the functional layers and contacts outside the device. The functional layers can generate electromagnetic signals (e.g., lights) or absorb electromagnetic signals.

System substrates can have pixels and pixel circuits that each pixel control at least one microdevice. Pixel circuits can be made of electrodes, transistors or other components. The transistors can be fabricated with a thin film process, CMOS, or organic materials.

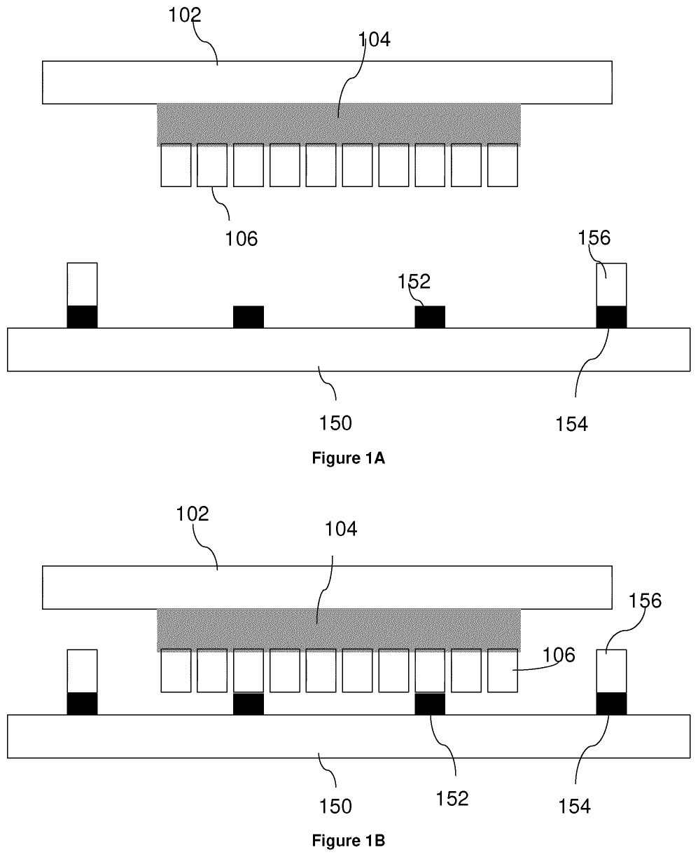

FIG. 1A shows an embodiment for transferring microdevices from the donor substrate 102 to the receiver substrate 150. Here, a buffer layer 104 can be formed on the donor substrate 102 and microdevices 106 are located on top of the buffer layer. The buffer layer can be formed by patterning or etching processes. It can be polymer, dielectric, or other materials such as metals. Due to the use of semiconductor processes to develop the buffer layer, it can be aligned to the edge of the last microdevices on the substrate. The system substrate 150 has pads 152 associated with the current microdevices to be transferred to the system substrate 150 from the donor substrate 102. The system substrate 150 also has pads 154 that have already been populated with microdevices 156 and some of these pads may be adjacent to the current location for the transfer.

As shown in FIG. 1B when the donor substrate 102 and system substrate 152 get close to each other, the selected microdevices are touching (or getting close to) the selected pads 152. The pads 152 can be soft materials (adhesive, polymers, Indium, and so on). As a result under pressure, the pads can deform. If the pressure is not uniform, the pads can deform differently and so damage the backplane, some of the existing microdevices in the backplane. In another case, the pads 152 are made of hard material. As a result, the pads will not deform. This can result in less losing connection for some devices due to surface non-uniformity or deviation in parallel between two substrates.

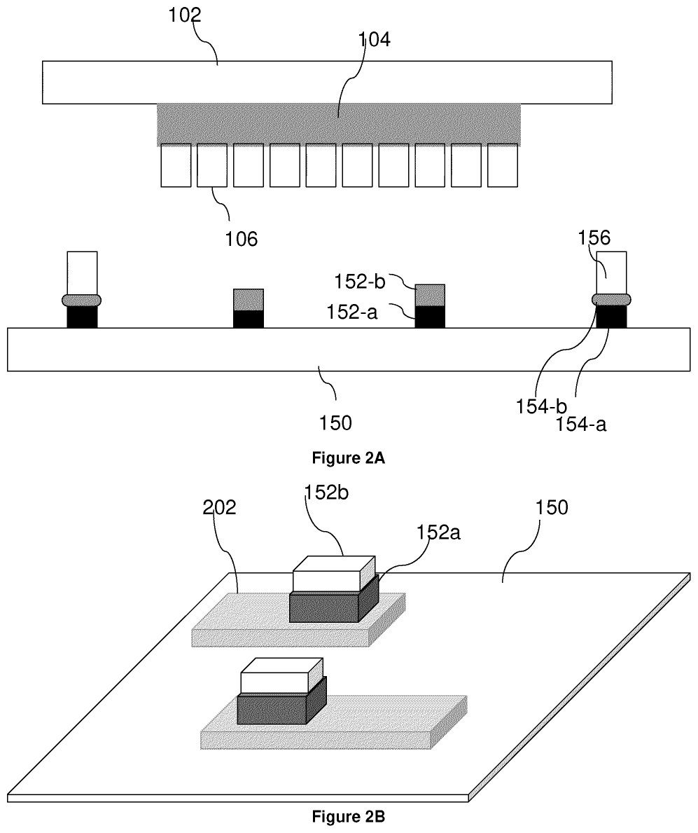

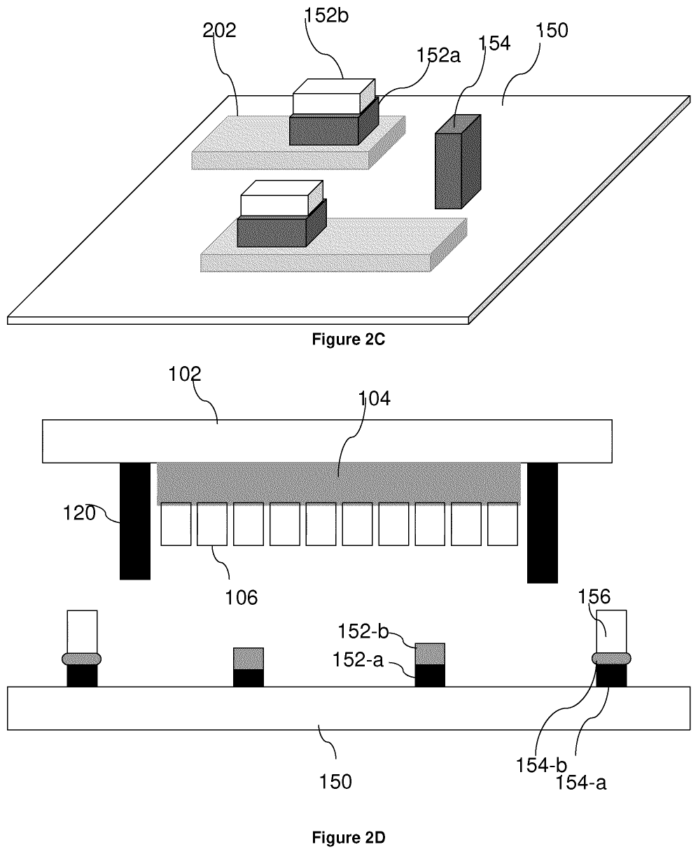

FIG. 2A shows an embodiment for transferring microdevices from the donor substrate 102 to the receiver substrate 150. Here, a buffer layer 104 can be formed on the donor substrate 102 and microdevices 106 are located on top of the buffer layer. The buffer layer can be formed by patterning or etching processes. It can be polymer, dielectric, or other materials such as metals. Due to the use of semiconductor processes to develop the buffer layer, it can be aligned to the edge of the last microdevices on the substrate. The system substrate 150 has pads 152 associated with the current microdevices to be transferred to the system substrate 150 from the donor substrate 102. The system substrate 150 also has pads 154 that have already been populated with microdevices 156 and some of these pads may be adjacent to the current location for the transfer. When the donor substrate 102 and system substrate 152 get close to each other, the selected microdevices are touching (or getting close to) the selected pads 152. In one related case, the pads have a hard material base 152-a and a soft shell 152-b. As it is seen, the transferred devices 156 can deform the soft material 154-b.

FIG. 2B shows a pad structure with hard core 152-a and soft shell 152-b. The shell 152-b can cover only the top surface of the core 152-a or at least one sidewall as well. Here, there can be electrodes 202 connecting the pads to the system substrate/backplane 150. The pads can have different shapes. The hard core can be hard metals such as Al, Gold, or dielectric such as silicon oxide or silicon nitride, or polymers such as BCB, SUB, etc., the shell can be indium or other soft metals or soft adhesive (such as PI, PMMA, PSA). The adhesive can have conductive particles embedded in it. The height of the hard core is designed to be taller than the surface difference between the highest point in the system substrate and the location of pads in the system substrate. Other parameters such as the surface non-uniformity of the two substrates and error in parallelism between the donor and the system substrates can be used to adjust the height of the hard core of the pad. In this case, the height is designed so that it prevents the microdevices touching the unwanted areas in the system substrate as it stops the donor substrate moving toward the system substrate. The height of the soft shell is designed to provide enough adhesion force, connection to the pads across the donor substrate. To achieve this, the soft material should be taller than the distance difference between pads on the system substrate and microdevices on the donor substrate. The distance difference can come from the error in the parallelism between two substrate and surface non-uniformities of the system substrate and donor substrate.

In another related embodiment, shown in FIG. 2C to further prevent the nonuniform pressure a post 154 can be developed on the backplane 150. Here the post gets in touch with the donor substrate 102 during the transfer and so eliminates damages on the pads, microdevices and backplane.

In another related embodiment, the posts 120 can be also formed on the donor substrate (FIG. 2D). The post can be made of metals or dielectric or polymer.

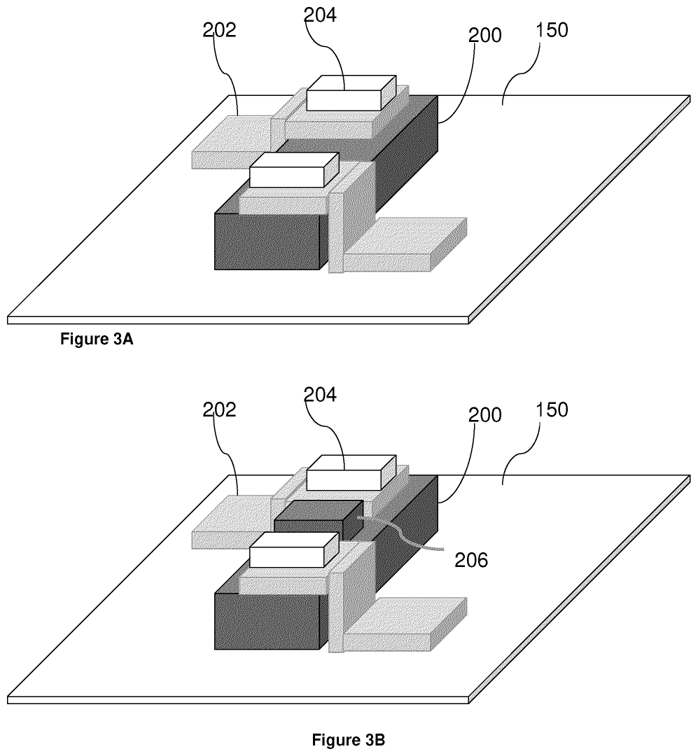

In another related case demonstrated in FIG. 3A, the pads on system substrate 150 are formed on a stage 200. Here, the electrode 202 is extended over top of the stage 200 and the pad 204 is formed on top of the electrode. As a result, during transfer as demonstrated in FIG. 1, the gap between donor substrate and system substrate will increase by the height of the stage. In another related case, there can be a post 206 or spacer (as shown in FIG. 3B) on the stage 200. The spacer 206 can prevent the short between two pads if the microdevice has more than one pads, also it can assist in the transfer of microdevice if it is adhesive.

### Method Steps

The present disclosure relates to a method to transfer microdevices the method comprising, forming a buffer layer on a donor substrate, having microdevices located on a top of the buffer layer, having a system substrate with transferred microdevices on pads made of a soft material, having other pads made of the soft material on the system substrate without microdevices, and bringing the donor and system substrate closer such that selected microdevices to be transferred are close to associated pads on the system substrate.

Further in the method the pads and other pads may be made of a hard material.

Further in the method, an electrode may be extended over top of a stage and the pad is formed on top of the electrode.

Further in the method, wherein there is a post on top of the stage and the pad is formed on top of the electrode.

The present disclosure relates to a method of transfer microdevices the method comprising, forming a buffer layer on a donor substrate, having microdevices located on a top of the buffer layer, having a system substrate with transferred microdevices on pads, with the pads having a hard material base and a soft shell, having other pads having a hard material base and a soft shell on the system substrate without microdevices, and bringing the donor and system substrate closer such that selected microdevices to be transferred are close to associated pads on the system substrate.

Further in the method, the buffer layer is formed by a patterning or an etching process and is a polymer, a dielectric, or a metal.

Further in the method, the soft shell of the pad covers only the top surface of the hard material base or at least one sidewall of the material base.

Further in the method, the hard material base is one of Al, Gold, or dielectric such as silicon oxide or silicon nitride, or polymers such as BCB, SU8 and the soft shell is one of indium or a soft adhesive. Here, the electrodes may be formed to connect the pads to the system substrate.

Further in the method, a post is developed on the system substrate such that it touches the donor substrate during a transfer eliminating damages on the pads, microdevices and system substrate. Here, posts may also be formed on the donor substrate and the posts are made of metals or dielectric or polymer.

Further in the method, a gap between donor substrate and system substrate increases by a height of the stage during transfer.

Further in the method, the height of the hard core is designed to be taller than the surface difference between the highest point in the system substrate and the location of pads in the system substrate. Other parameters such as the surface non-uniformity of the two substrates and error in parallelism between the donor and the system substrates can be used to adjust the height of the hard core of the pad. In this case, the height is designed so that it prevents the microdevices touching the unwanted areas in the system substrate as it stops the donor substrate moving toward the system substrate. The height of the soft shell is designed to provide enough adhesion force, connection to the pads across the donor substrate. To achieve this, the soft material should be taller than the distance difference between pads on the system substrate and microdevices on the donor substrate. The distance difference can come from the error in the parallelism between two substrate and surface non-uniformities of the system substrate and donor substrate.

While particular embodiments and applications of the present invention have been illustrated and described, it is to be understood that the invention is not limited to the precise construction and compositions disclosed herein and that various modifications, changes, and variations can be apparent from the foregoing descriptions without departing from the spirit and scope of the invention as defined in the appended claims.

1. A method to transfer microdevices the method comprising:
forming a buffer layer on a donor substrate;
having microdevices located on a top of the buffer layer;
having a system substrate with transferred microdevices on pads made of a soft material;
having other pads made of the soft material on the system substrate without microdevices; and
bringing the donor and system substrate closer such that selected microdevices to be transferred are close to associated pads on the system substrate.

2. The method of claim 1, wherein the pads and other pads are made of a hard material.

3. A method to transfer microdevices the method comprising:
forming a buffer layer on a donor substrate;
having microdevices located on a top of the buffer layer;
having a system substrate with transferred microdevices on pads, with the pads having a hard material base and a soft shell;
having other pads having a hard material base and a soft shell on the system substrate without microdevices; and
bringing the donor and system substrate closer such that selected microdevices to be transferred are close to associated pads on the system substrate.

4. The method of claim 3, wherein the buffer layer is formed by a patterning or an etching process and is a polymer, a dielectric or a metal.

5. The method of claim 3, wherein the soft shell of the pad covers only a top surface of the hard material base or at least one sidewall of the material base.

6. The method of claim 3, wherein the hard material base is one of Al, Gold, or dielectric such as silicon oxide or silicon nitride, or polymers such as BCB, SU8 and the soft shell is one of indium or a soft adhesive.

7. The method of claim 3, wherein a post is developed on the system substrate such that it touches the donor substrate during a transfer eliminating damages on the pads, microdevices and system substrate.

8. The method of claim 5, wherein electrodes are formed to connect the pads to the system substrate.

9. The method of claim 7, wherein posts are also formed on the donor substrate.

10. The method of claim 9, wherein the posts are made of metals or dielectric or polymer.

11. The method of claim 1, wherein an electrode is extended over top of a stage and the pad is formed on top of the electrode.

12. The method of claim 11, wherein a gap between donor substrate and system substrate increases by a height of the stage during transfer.

13. The method of claim 1, wherein there is a post on top of the stage and the pad is formed on top of the electrode.
